(19) United States
(12) Patent Application Publication
(10) Pub. No.: US 2012/0146040 A1
(43) Pub. Date: Jun. 14, 2012

(54) SUBSTRATE AND DISPLAY DEVICE INCLUDING THE SAME

(75) Inventors: Jung-Min LEE, Yongin-city (KR); Choong-Ho LEE, Yongin-city (KR)

(73) Assignee: SAMSUNG MOBILE DISPLAY CO., LTD., Yongin-city (KR)

(21) Appl. No.: 13/069,284

(22) Filed: Mar. 22, 2011

(30) Foreign Application Priority Data
Dec. 14, 2010 (KR) 10-2010-0127647

(51) Int. Cl. H01L 33/16; B32B 15/08; B32B 15/092; B32B 15/04

(52) U.S. Cl. 257/72; 428/457; 428/458; 428/418; 428/335; 428/332; 428/450; 428/447; 257/E33.003

(57) ABSTRACT

Disclosed is a substrate for a display device that includes a composite material layer including an inorganic fiber material and a resin, and a metal layer disposed on the composite material layer, and a display device including the substrate.

### CROSS-REFERENCE TO RELATED APPLICATIONS

This application claims priority to and the benefit of Korean Patent Application No. 10-2010-0127647 filed in the Korean Intellectual Property Office on Dec. 14, 2010, the entire contents of which are incorporated herein by reference.

### BACKGROUND

1. Field

The disclosure is related to a substrate and a display device including the substrate.

2. Description of the Related Technology

A display device such as an organic light emitting device and a liquid crystal display (LCD) includes a substrate.

The substrate for a display device may in general include a glass substrate, a plastic substrate, or the like.

However, since the glass substrate is heavy and fragile, it may be damaged by an external impact as well as have a limit in realizing a portable display and a big screen. Accordingly, it may not be appropriately applied to a flexible display device.

The plastic substrate is made of a plastic material and thus, may have an advantage of portability, safety, lightness, and the like compared with the glass substrate. In addition, since the plastic substrate is fabricated through deposition or printing, a cost of manufacturing may be lowered. Further, since a display device including the plastic substrate may be fabricated in a roll-to-roll process rather than a conventional sheet unit process, it may be mass produced with a low cost.

However, the plastic substrate may be deteriorated due to permeability and oxygen transmission of a plastic material and transformed at a high temperature due to weak heat resistance, resultantly having an influence on a device formed thereon.

### SUMMARY OF CERTAIN INVENTIVE ASPECTS

One aspect of the present invention provides a substrate with excellent water and heat resistances applicable to a flexible display device.

Another aspect of the present invention provides a display device including the substrate.

According to one embodiment, a substrate for a display device is provided that includes a composite material layer including an inorganic fiber material and a resin, and a metal layer disposed on the composite material layer.

The inorganic fiber material may include a carbon fiber, a Kevlar fiber, or a combination thereof.

The resin may have a thermal expansion ratio ranging from about 20*10⁻⁷ [1/° C.] to about 50*10⁻⁷ [1/° C.] at a temperature ranging from about 200 to about 400° C.

The resin may include a polyimide resin, a bismaleimide-based resin, a phenol resin, an epoxy resin, a novolac resin, a derivative thereof, or a combination thereof.

The composite material layer may have fracture toughness of at least about 12 MPa·m^{1/2}.

The metal layer may include aluminum (Al), copper (Cu), nickel (Ni), an alloy thereof, or a combination thereof.

The metal layer may have a thickness ranging from about 10 μm to about 1000 μm.

The metal layer may have a thickness ranging from about 10 μm to about 50 μm.

The substrate may further include an insulation layer disposed on the metal layer.

The insulation layer may include silicon oxide, silicon nitride, or a combination thereof.

In another aspect, a display device is provided that includes a substrate, a thin film transistor disposed on the substrate, and a pixel electrode that is electrically connected to the thin film transistor, wherein the substrate includes a composite material layer comprising an inorganic fiber material and a resin and a metal layer disposed on the composite material layer.

The thin film transistor may include polycrystalline silicon.

The display device may include a common electrode facing with the pixel electrode and an emission layer disposed between the pixel electrode and the common electrode. The common electrode may be a transparent electrode.

The inorganic fiber material may include a carbon fiber, a Kevlar fiber, or a combination thereof.

The resin may have a thermal expansion ratio ranging from about 20*10⁻⁷ [1/° C.] to about 50*10⁻⁷ [1/° C.] at a temperature ranging from about 200 to about 400° C.

The resin may include a polyimide resin, a bismaleimide-based resin, a phenol resin, an epoxy resin, a novolac resin, a derivative thereof, or a combination thereof.

The metal layer may include aluminum (Al), copper (Cu), nickel (Ni), an alloy thereof, or a combination thereof.

The substrate may further include an insulation layer disposed on the metal layer.

The insulation layer may include silicon oxide, silicon nitride, or a combination thereof.

Embodiments provide a substrate applicable to a flexible display device and having excellent water and heat resistances.

### BRIEF DESCRIPTION OF THE DRAWINGS

FIG. 1 is a cross-sectional view schematically showing an embodiment of a substrate for a display device, and

FIG. 2 is a cross-sectional view illustrating an embodiment of a display device.

### DETAILED DESCRIPTION OF CERTAIN INVENTIVE EMBODIMENTS

The present disclosure will be described more fully hereinafter with reference to the accompanying drawings, in which certain embodiments of this disclosure are shown. This disclosure may, however, be embodied in many different forms and is not construed as limited to the embodiments set forth herein.

In the drawings, the thickness of layers, films, panels, regions, etc., may be exaggerated for clarity. Like reference numerals generally designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

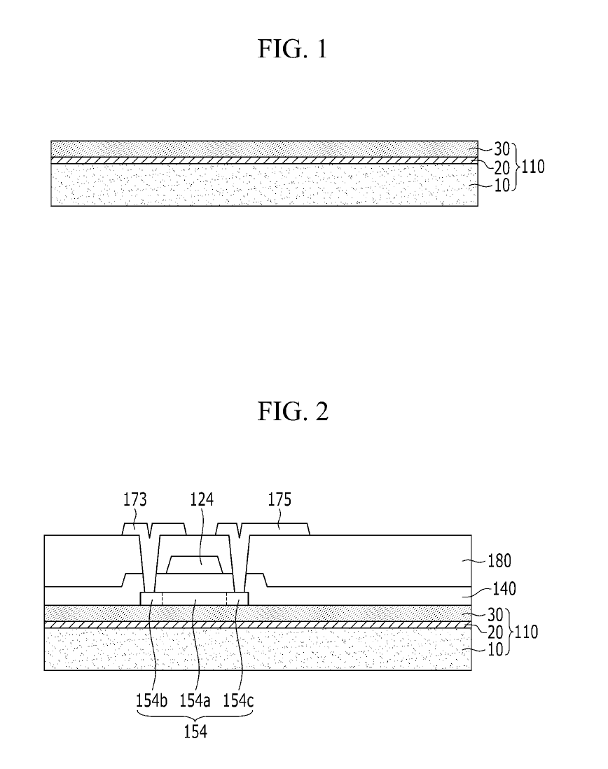

FIG. 1 is a cross-sectional view schematically illustrating an embodiment of a substrate for a display device.

According to one embodiment, a substrate 110 for a display device may include a composite material layer 10, a metal layer 20 disposed on the composite material layer 10, and an insulation layer 30 disposed on the metal layer 20.

The composite material layer 10 works as a support for a substrate for a display device and can be flexible.

The composite material layer 10 can include an inorganic fiber material and a resin.

The inorganic fiber material forms a frame for the composite material layer 10 and helps absorb mechanical strength coming from outside, or transfer the mechanical strength to another layer. Accordingly, the inorganic fiber material may prevent the composite material layer 10 from being easily broken by external strength.

In various embodiments, the inorganic fiber material may include, for example, carbon fiber, Kevlar fiber, or a combination thereof.

The resin may fix the inorganic fiber material and may also prevent transmission of external moisture and oxygen.

The resin may also determine thermal stability of the substrate 110. The resin can have a thermal expansion ratio ranging from about about 20*10⁻⁷ [1/° C.] to about 50*10⁻⁷ [1/° C.] at a temperature ranging from about 200 to 400° C.

When the resin has a thermal expansion ratio within this range, it does not contractor expand much during the process of forming a plurality of thin films and thus, contributes to fabricating a stable device.

In various embodiments, the resin can include a polyimide resin, a bismaleimide-based resin, a phenol resin, an epoxy resin, a novolac resin, a derivative thereof, or a combination thereof.

The composite material layer 10 may have a fracture toughness of about 12 MPa·m^{1/2} or more. The fracture toughness indicates how long a composite material layer 10 can last when it has a crack. The composite material layer 10 has a relatively high fracture toughness compared with about 0.85 MPa·m^{1/2} of the fracture toughness of glass. When a composite material layer 10 has fracture toughness within this range, it may endure external impact and an appropriate load and be flexible.

The metal layer 20 may prevent transmission of external moisture and oxygen and thus, degradation of the device.

In various embodiments, the metal layer 20 may include, for example, aluminum (Al), copper (Cu), nickel (Ni), an alloy thereof, or a combination thereof.

The metal layer 20 may have a thickness ranging from about 10 to about 1000 μm. In some embodiments, the metal layer 20 may have a thickness ranging from about 10 to 50 μm.

The insulation layer 30 may play a role of insulating the metal layer 20 from a device formed thereon and prevent degradation of a substrate due to laser heat when a laser is radiated to from a crystalline semiconductor on the substrate.

The insulation layer 30 may include silicon oxide, silicon nitride, or a combination thereof.

In some embodiments, the insulation layer 30 may be omitted.

The substrate 110 including the composite material layer 10, the metal layer 20, and the insulation layer 30 is strong and flexible against an external impact and thus, has high durability compared with a glass substrate. In addition, a glass substrate typically includes a large amount of an alkali component, which may move toward a device during the process or after the process and thus, degrade the device. However, since a substrate according to one embodiment does not include an alkali component, it may prevent degradation of a device.

In addition, since the aforementioned substrate has flexible characteristic regardless of thickness, it may be about 0.1 mm thick to realize a thin display device or about 0.5 mm thick to realize a display device with high durability.

Referring to FIG. 2, illustrated is an embodiment of a display device including the substrate 110. FIG. 2 is a cross-sectional view showing an embodiment of a display device.

As aforementioned, a substrate 110 may include a composite material layer 10, a metal layer 20 disposed on the composite material layer 10, and an insulation layer 30 on the metal layer 20.

A polycrystalline silicon layer 154 is disposed on the substrate 110. The polycrystalline silicon layer 154 may be formed of crystalline silicon and include a channel region 154a not doped with impurity and a source region 154b and a drain region 154c doped with impurities.

A gate insulating layer 140 is formed on the polycrystalline silicon layer 154. The gate insulating layer 140 is formed on the whole of the substrate 110 and may be formed of silicon oxide or silicon nitride. The gate insulating layer 140 has contact holes respectively exposing the source region 154b and the drain region 154c.

A gate electrode 124 is formed on the gate insulating layer 140. The gate electrode 124 is overlapped with the channel region 154a of the polycrystalline silicon layer 154.

A passivation layer 180 is formed on a gate electrode 124. The passivation layer 180 has contact holes respectively exposing the source region 154b and the drain region 154c.

A source electrode 173 and a drain electrode 175 are disposed on the passivation layer 180. The source electrode 173 is connected to the source region 154b of the polycrystalline silicon layer 154 through the contact hole in the passivation layer 180 and the gate insulating layer 140. The drain electrode 175 is connected to the drain region 154c of the polycrystalline silicon layer 154 through the contact hole in the passivation layer 180 and the gate insulating layer 140.

The polycrystalline silicon layer 154, the gate electrode 124, the source electrode 173, and the drain electrode 175 form a thin film transistor (TFT).

A pixel electrode (not shown) is formed on the thin film transistor. The pixel electrode is electrically connected to the thin film transistor.

In embodiments where the display device is an organic light emitting device, the device may further include a common electrode (not shown) facing the pixel electrode, and an emission layer (not shown) between the pixel electrode and the common electrode.

The substrate 110 includes the composite material layer 10 and the metal layer 20 and thus, is not very transparent. The device may emit a light through the opposite side of the substrate 110, that is, the side of the common electrode. Accordingly, it may have a top emission structure. The common electrode may be a transparent electrode.

An embodiment of a method of manufacturing the display device referring to FIG. 2 is described below.

A composite material layer 10 is formed by putting a resin solution including an inorganic fiber material, such as carbon fiber, Kevlar fiber, and the like, and an organic resin, such as a polyimide resin, a bismaleimide-based resin, a phenol resin, an epoxy resin, a novolac resin, and the like, in a predetermined mold.

Next, a metal, such as aluminum (Al), copper (Cu), nickel (Ni), an alloy thereof, and the like, is disposed on the composite material layer 10 by sputtering or similar process to form a metal layer 20.

Then, an insulation layer 30 is disposed on the metal layer 20 by a chemical vapor deposition (CVD) using silicon oxide, silicon nitride, or the like.

The substrate including the composite material layer 10, the metal layer 20, and the insulation layer 30 may be processed without a separate carrier like a glass. Accordingly, compared with a polymer substrate requiring a glass carrier to prevent the polymer substrate from being bent, the substrate may be easily fabricated and can have no static electricity when a glass carrier is separated therefrom.

Then, an amorphous silicon layer (not shown) is laminated on the substrate 110 and patterned. Next, the patterned amorphous silicon layer is radiated by a laser to form a polycrystalline silicon layer 154.

The polycrystalline silicon layer 154 is doped with p-type or n-type impurities except for a channel region 154a to form a source region 154b and a drain region 154c.

Next, a gate insulating layer 140 is laminated on the whole of the substrate.

A gate electrode 124 is disposed, where it is overlapped with the channel region 154a of the polycrystalline silicon layer 154 on the gate insulating layer 140.

Then, a passivation layer 180 is laminated on the whole of the substrate including the gate electrode 124. The passivation layer 180 and the gate insulating layer 140 are lithographed to form a contact hole exposing a source region 154b and a drain region 154c.

Then, a conductive layer is disposed on the passivation layer 180 and patterned to form a source electrode 173 connected to the source region 154b and a drain electrode 175 connected to the drain region 154c.

Next, a pixel electrode (not shown) connected to the drain electrode 175 is formed.

In embodiments where the display device is an organic light emitting device, an organic emission layer and a common electrode are also sequentially laminated on the pixel electrode.

While this disclosure has been described in connection with certain embodiments, it is to be understood that the invention is not limited to the disclosed embodiments, but, on the contrary, is intended to cover various modifications and equivalent arrangements included within the spirit and scope of the appended claims.

What is claimed is:

1. A substrate for a display device, comprising:
a composite material layer comprising an inorganic fiber material and a resin, and
a metal layer disposed on the composite material layer.

2. The substrate of claim 1, wherein the inorganic fiber material comprises a carbon fiber, a Kevlar fiber, or a combination thereof.

3. The substrate of claim 1, wherein the resin has a thermal expansion ratio of about 20*10⁻⁷ [1/° C.] to about 50*10⁻⁷ [1/° C.] at about 200 to about 400° C.

4. The substrate of claim 1, wherein the resin comprises a polyimide resin, a bismaleimide-based resin, a phenol resin, an epoxy resin, a novolac resin, a derivative thereof, or a combination thereof.

5. The substrate of claim 1, wherein the composite material layer has a fracture toughness of at least about 12 MPa·m^{1/2}.

6. The substrate of claim 1, wherein the metal layer comprises aluminum (Al), copper (Cu), nickel (Ni), an alloy thereof, or a combination thereof.

7. The substrate of claim 1, wherein the metal layer has a thickness of about 10 μm to about 1000 μm.

8. The substrate of claim 1, wherein the metal layer has a thickness of about 10 μm to about 50 μm.

9. The substrate of claim 1, wherein the substrate further comprises an insulation layer disposed on the metal layer.

10. The substrate of claim 9, wherein the insulation layer comprises silicon oxide, silicon nitride, or a combination thereof.

11. A display device comprising
a substrate,
a thin film transistor disposed on the substrate, and
a pixel electrode electrically connected to the thin film transistor,
wherein the substrate comprises:
a composite material layer comprising an inorganic fiber material and a resin, and
a metal layer disposed on the composite material layer.

12. The display device of claim 11, wherein the thin film transistor comprises polycrystalline silicon.

13. The display device of claim 11, further comprising a common electrode facing the pixel electrode, and
an emission layer disposed between the pixel electrode and the common electrode,
wherein the common electrode is a transparent electrode.

14. The display device of claim 11, wherein the inorganic fiber material comprises a carbon fiber, a Kevlar fiber, or a combination thereof.

15. The display device of claim 11, wherein the resin has a thermal expansion ratio of about 20*10⁻⁷ [1/° C.] to about 50*10⁻⁷ [1/° C.] at about 200 to about 400° C.

16. The display device of claim 11, wherein the resin comprises a polyimide resin, a bismaleimide-based resin, a phenol resin, an epoxy resin, a novolac resin, a derivative thereof, or a combination thereof.

17. The display device of claim 11, wherein the metal layer comprises aluminum (Al), copper (Cu), nickel (Ni), an alloy thereof, or a combination thereof.

18. The display device of claim 11, wherein the substrate further comprises an insulation layer disposed on the metal layer.

19. The display device of claim 18, wherein the insulation layer comprises silicon oxide, silicon nitride, or a combination thereof.
